(19) United States
(12) Patent Application Publication
(10) Pub. No.: US 2024/0204136 A1
(43) Pub. Date: Jun. 20, 2024

(54) PHOTOELECTRIC CONVERSION ELEMENT AND GAS SENSOR

(71) Applicant: Asahi Kasei Microdevices Corporation, Tokyo (JP)

(72) Inventor: Toshiaki FUKUNAKA, Tokyo (JP)

(73) Assignee: Asahi Kasei Microdevices Corporation, Tokyo (JP)

(21) Appl. No.: 18/522,793

(22) Filed: Nov. 29, 2023

(30) Foreign Application Priority Data
Dec. 20, 2022 (JP) 2022-203710
Sep. 5, 2023 (JP) 2023-143970

(51) Int. Cl. H01L 33/20; H01L 23/498; H01L 33/38; H01L 33/62

(52) U.S. Cl. CPC H01L 33/20; H01L 23/49816; H01L 33/382; H01L 33/62

(57) ABSTRACT

A photoelectric conversion element includes a semiconductor module (21) including a semiconductor element member (10) and a seal (20) covering a side of the semiconductor element member, the semiconductor element member including a light emission/irradiation surface (10a) configured to emit or be irradiated by light, a semiconductor substrate (111), a semiconductor layer (112), and an electrode (113), and an insulating layer (31) provided on one surface of the semiconductor module and covering a redistribution wire of the electrode and of an external connection terminal. The insulating layer includes a first insulating layer (311) and a second insulating layer (312) with the redistribution wire provided therebetween and is formed so as not to cover at least a portion of the semiconductor layer, or so as to cover at least a portion of the semiconductor layer thinly as compared to the thickness of the insulating layer that covers the redistribution wire.

### CROSS-REFERENCE TO RELATED APPLICATION

The present application claims priority to Japanese Patent Application No. 2022-203710 filed on Dec. 20, 2022, and Japanese Patent Application No. 2023-143970 filed on Sep. 5, 2023, the entire contents of which are incorporated herein by reference.

### TECHNICAL FIELD

The present disclosure relates to a photoelectric conversion element and a gas sensor.

### BACKGROUND

An infrared light-receiving element (infrared sensor) that outputs a signal in accordance with received infrared light and an infrared light-emitting element (infrared light-emitting diode (LED)) that emits infrared light in response to input electrical power are known semiconductor elements. A quantum infrared light-receiving element detects infrared light through photoelectric current generated when a semiconductor having a pn junction or pin junction absorbs infrared light. An infrared light-emitting element emits infrared light through voltage applied in a forward direction. Infrared light-receiving elements and infrared light-emitting elements may be used in non-dispersive infrared (NDIR) gas sensors, for example. An NDIR gas sensor can measure gas concentration using an infrared light-receiving element that receives infrared light of an absorption wavelength band in accordance with a detection target gas and an infrared light-emitting element that emits infrared light of this absorption wavelength band. For example, Patent Literature (PTL) 1 discloses an apparatus in which a light source that emits infrared light and a detector that detects infrared light of a specific wavelength are provided in a case having an ellipsoidal inner surface (ellipsoidal mirror), and a gas that is to be detected is introduced into the case.

### CITATION LIST

### Patent Literature

PTL 1: US 2018/0348121 A1

### SUMMARY

In a device having a configuration in which a semiconductor element is arranged on a substrate, the semiconductor substrate may also be subjected to stress. For example, warping of the semiconductor substrate may occur under the influence of thermal expansion during device mounting or the like. In a case in which the device is a gas sensor, this warping may cause characteristic variation of the gas sensor. Particularly with regard to small gas sensors, deformation of a semiconductor substrate has a significant effect on characteristics, and thus there is demand for a technique that can suppress the effect on semiconductor elements.

It could be helpful to provide a photoelectric conversion element and a gas sensor that can suppress characteristic variation caused by deformation of a semiconductor substrate.

(1) A photoelectric conversion element according to an embodiment of the present disclosure includes:
a semiconductor module including a semiconductor element member and a seal covering a side of the semiconductor element member, the semiconductor element member including a light emission/irradiation surface configured to emit light or to be irradiated by light, a semiconductor substrate, a semiconductor layer, and an electrode; and
an insulating layer provided on one surface of the semiconductor module and covering a redistribution wire of the electrode and of at least one external connection terminal,
wherein the insulating layer is configured to include a first insulating layer and a second insulating layer, the redistribution wire being provided between the first insulating layer and the second insulating layer, and is formed so as not to cover at least a portion of the semiconductor layer, or so as to cover at least a portion of the semiconductor layer thinly as compared to a thickness of the insulating layer that covers the redistribution wire.

(2) As an embodiment of the present disclosure, in (1), in a case in which the insulating layer is formed to cover at least a portion of the semiconductor layer thinly, the second insulating layer is not provided at a thinly covering portion of the insulating layer.

(3) As an embodiment of the present disclosure, in (1) or (2), the photoelectric conversion element has a fan out wafer level package structure.

(4) As an embodiment of the present disclosure, in any one of (1) to (3), in a case in which the semiconductor layer is divided into a connection region in which the electrode can be disposed and a central region excluding the connection region, the insulating layer is formed so as not to cover a portion of the connection region or so as to cover a portion of the connection region thinly as compared to the thickness of the insulating layer that covers the redistribution wire.

(5) As an embodiment of the present disclosure, in any one of (1) to (3), in a case in which the semiconductor layer is divided into a connection region in which the electrode can be disposed and a central region excluding the connection region, the insulating layer is formed so as not to cover the central region or so as to cover the central region thinly as compared to the thickness of the insulating layer that covers the redistribution wire.

(6) As an embodiment of the present disclosure, in any one of (1) to (3), in a case in which the semiconductor layer is divided into a connection region in which the electrode can be disposed and a central region excluding the connection region, the insulating layer is formed so as not to cover the central region and a portion of the connection region or so as to cover the central region and a portion of the connection region thinly as compared to the thickness of the insulating layer that covers the redistribution wire.

(7) As an embodiment of the present disclosure, in any one of (1) to (6), the at least one external connection terminal includes a plurality of external connection terminals and forms a land grid array or a ball grid array.

(8) A gas sensor according to an embodiment of the present disclosure includes:
a light-emitting element that is the photoelectric conversion element according to any of (1) to (7), the light emission/irradiation surface of the light-emitting element being configured to emit light; and
a light-receiving element that is the photoelectric conversion element according to any of (1) to (7), the light emission/irradiation surface of the light-receiving element being configured to be irradiated by light,
wherein the gas sensor is configured to detect a detection target gas contained in a gas, based on a received light amount of the light that is emitted from the light-emitting element, passes through the gas, and is detected by the light-receiving element.

(9) As an embodiment of the present disclosure, in any one of (1) to (7), in a case in which the insulating layer is formed to include a thinly covering portion that covers at least a portion of the semiconductor layer thinly, the thinly covering portion has a thickness that is equal to or less than ½ of a combined thickness of the first insulating layer and the second insulating layer.

According to the present disclosure, a photoelectric conversion element and a gas sensor that can suppress characteristic variation caused by deformation of a semiconductor substrate can be provided.

### BRIEF DESCRIPTION OF THE DRAWINGS

In the accompanying drawings:

FIG. 1 is a schematic diagram illustrating a configuration example of a gas sensor according to an embodiment of the present disclosure;

FIG. 2 is a cross-sectional view illustrating a cross-section of the gas sensor illustrated in FIG. 1;

FIG. 3 is a plan view illustrating an upper surface of the gas sensor illustrated in FIG. 1 with a light guide removed;

FIG. 4 is a plan view illustrating the upper surface of the gas sensor illustrated in FIG. 1;

FIG. 5 is a cross-sectional view illustrating a partially enlarged cross-section including a photoelectric conversion element of the gas sensor illustrated in FIG. 1;

FIG. 6 is a diagram illustrating stress applied to a photoelectric conversion element;

FIG. 7 is a plan view of a case in which the photoelectric conversion element is a light-emitting element;

FIG. 8 is a plan view of a case in which the photoelectric conversion element is a light-receiving element;

FIG. 9A is a cross-sectional view illustrating an example configuration of an insulating layer of the photoelectric conversion element;

FIG. 9B is a cross-sectional view illustrating an example configuration of the insulating layer of the photoelectric conversion element;

FIG. 9C is a cross-sectional view illustrating an example configuration of the insulating layer of the photoelectric conversion element;

FIG. 9D is a cross-sectional view illustrating an example configuration of the insulating layer of the photoelectric conversion element;

FIG. 9E is a cross-sectional view illustrating an example configuration of the insulating layer of the photoelectric conversion element; and

FIG. 9F is a cross-sectional view illustrating an example configuration of the insulating layer of the photoelectric conversion element.

### DETAILED DESCRIPTION

A photoelectric conversion element and a gas sensor according to an embodiment of the present disclosure are described below with reference to the drawings. Parts in the drawings that are the same or correspond are allotted the same reference signs. In the description of the present embodiment, descriptions of parts that are the same or correspond may be omitted or abbreviated as appropriate.

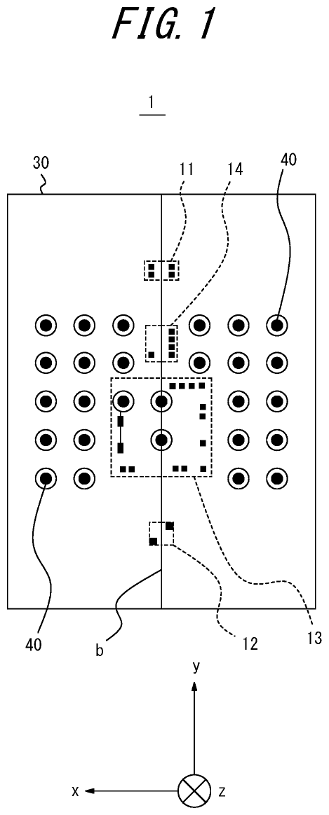

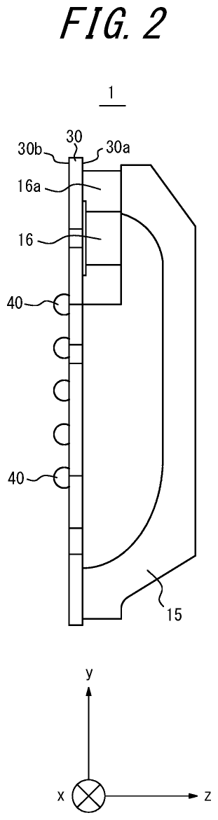

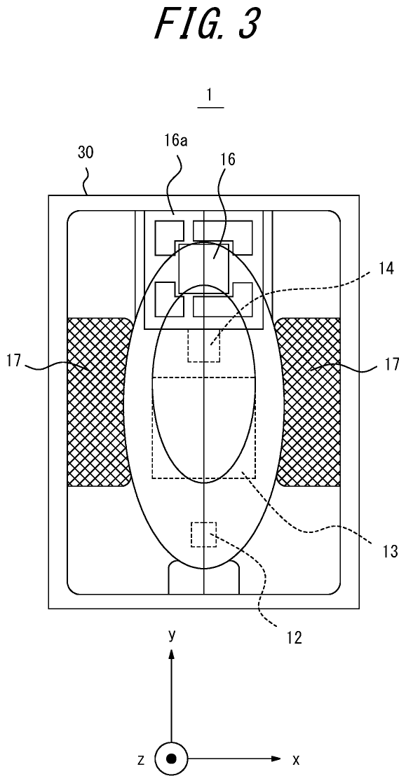

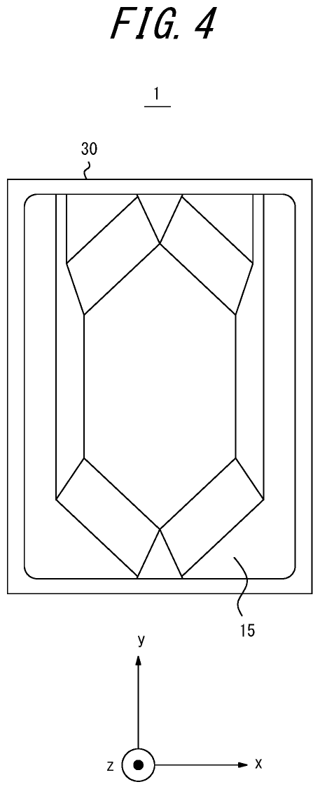

FIG. 1 is a schematic diagram illustrating a configuration example of a gas sensor 1 according to the present embodiment. In FIG. 1, a substrate is illustrated transparently in order to illustrate positions of a light-emitting element 11, a light-receiving element 12, and so forth. FIG. 2 is a cross-sectional view illustrating a cross-section of the gas sensor 1 at an imaginary line b at the center of FIG. 1. FIG. 3 and FIG. 4 are plan views illustrating an upper surface of the gas sensor 1. FIG. 3 illustrates the gas sensor 1 with a light guide 15 thereof removed (i.e., transparent).

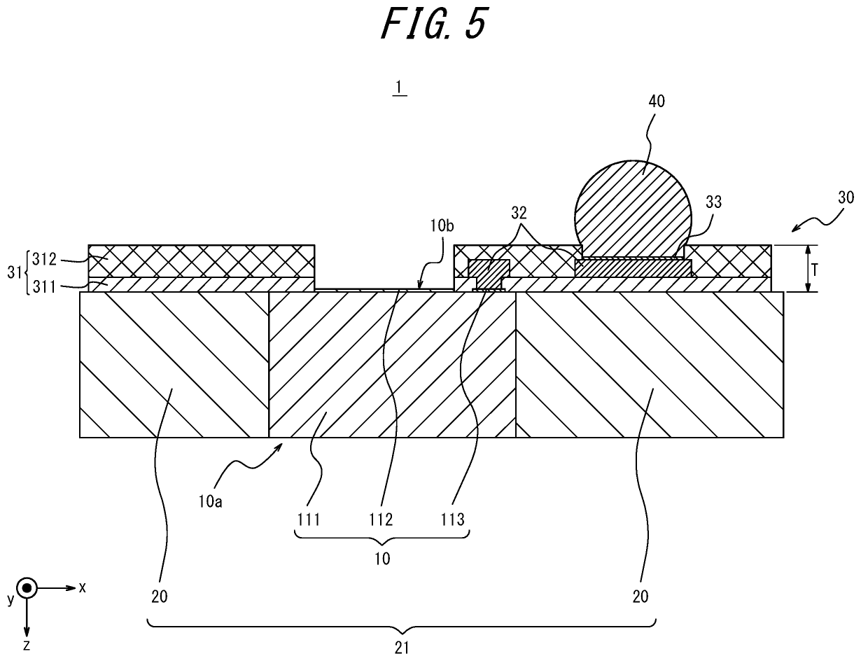

In FIGS. 1 to 4, Cartesian coordinates are set in correspondence with the orientation of the gas sensor 1. These Cartesian coordinates are also used in FIG. 5 and FIG. 7 to FIG. 9F, referred to below. The z-axis direction is the height direction of the gas sensor 1. The y-axis direction corresponds to the vertical direction of the gas sensor 1 and corresponds to the longitudinal direction of a substrate having a rectangular shape in the present embodiment. The x-axis direction corresponds to a horizontal direction (width direction) of the gas sensor 1 and corresponds to a transverse direction of the substrate having a rectangular shape in the present embodiment. Note that the substrate may have a square shape, and, in this case, the x-axis direction and the y-axis direction may correspond to the direction of one side and a direction orthogonal thereto. Positional relationships are described below using these Cartesian coordinate axes.

As illustrated in FIGS. 1 to 4, the gas sensor 1 includes a substrate, a light-emitting element 11, a light-receiving element 12, and a plurality of external connection terminals 40. In the present embodiment, the gas sensor 1 further includes a light guide 15 that guides light emitted from the light-emitting element 11 to the light-receiving element 12 and a filter block 16a resin molded with an optical filter 16 at an emission surface of the light-emitting element 11. In the present embodiment, the gas sensor 1 further includes an integrated circuit (IC) 13 that controls operation of the light-emitting element 11 and the light-receiving element 12 and that computes the concentration of a gas that is to be detected and a memory 14 that stores data, a program, or the like used by the IC 13. At least a portion of the plurality of external connection terminals 40 is electrically connected to the light-emitting element 11 and the light-receiving element 12. A portion of the plurality of external connection terminals 40 may be electrically connected to the IC 13 or the memory 14. Furthermore, either or both of the light-emitting element 11 and the light-receiving element 12 may be directly electrically connected to the IC 13. Also, the memory 14 may be omitted in a case in which a memory 14 can be provided in the IC 13. It is not essential that the gas sensor 1 includes the IC 13 in a case in which an IC 13 is provided externally. It is also not essential that the gas sensor 1 includes the memory 14 in a case in which a memory 14 is provided externally.

In a device having a semiconductor element sealed by resin, a package structure such as a fan out wafer level package (FOWLP) or a wafer level chip size package (WLCSP) may be adopted for the purpose of device miniaturization. In the present embodiment, the light-emitting element 11, the light-receiving element 12, the IC 13, and the memory 14 are semiconductor elements, and the gas sensor 1 embodies a small detection device having an FOWLP package structure. For example, the light-emitting element 11 and the light-receiving element 12 may each have a FOWLP package structure. A reconfigured substrate is used to mount and electrically connect these semiconductor elements. In the present embodiment, the reconfigured substrate includes a redistribution layer 30 that is formed at an electrode formation surface side of the light-emitting element 11 and the light-receiving element 12. The redistribution layer 30 is described in detail further below. In the following description, one surface of the substrate that is a surface where the semiconductor elements are provided and that emits light or is irradiated by light is referred to as a front surface 30a. An opposite surface of the substrate to the front surface 30a is a surface where the plurality of external connection terminals 40 is provided and is referred to as a rear surface 30b. The light-emitting element 11, the light-receiving element 12, and the like also individually include a substrate that is a constituent of the element. The substrate of the element is referred to herein as a semiconductor substrate 111 (refer to FIG. 5). A product in which the gas sensor 1 is used as a component also includes a substrate. The substrate of the product is referred to herein as a product substrate. Note that the phrase “at the rear surface 30b” as used herein is inclusive not only of a state of being present directly on the rear surface 30b but also of a state of being present indirectly on the rear surface 30b. For example, the plurality of external connection terminals 40 may be provided at the rear surface 30b with another layer or the like in-between, and such indirect placement is also referred to as “at the rear surface 30b”.

The light emission/irradiation surface 10a (i.e., the light-emission surface) of the light-emitting element 11 is provided at the front surface 30a of the substrate and emits light used to detect a gas that is to be detected. No specific limitations are placed on the light-emitting element 11 so long as it outputs light including a wavelength that is absorbed by the gas that is to be detected. The light emitted by the light-emitting element 11 is infrared light in the present embodiment but is not limited to infrared light. The light-emitting element 11 is an LED in the present embodiment, but other examples thereof include a semiconductor laser, a microelectromechanical systems (MEMS) heater, and the like. The phrase “provided at the front surface 30a” as used herein is inclusive not only of provision directly on the front surface 30a but also of provision indirectly on the front surface 30a. For example, the filter block 16a may be provided at the front surface 30a of the substrate with an adhesive or the like in-between, and such indirect placement is also referred to as “provided at the front surface 30a”.

The wavelength of the infrared light may be 2 μm to 12 μm. The region of 2 μm to 12 μm is a wavelength band that is particularly suitable for use in the gas sensor 1 due to a large number of absorption bands that are characteristic of various gases being present in this region. For example, an absorption band for methane is present at a wavelength of 3.3 μm, an absorption band for carbon dioxide is present at a wavelength of 4.3 μm, and an absorption band for alcohol (ethanol) is present at a wavelength of 9.5 μm.

The light emission/irradiation surface 10a (i.e., the light-irradiation surface) of the light-receiving element 12 is provided at the front surface 30a of the substrate and receives light emitted from the light-emitting element 11. No specific limitations are placed on the light-receiving element 12 so long as it has sensitivity to a band of light including a wavelength that is absorbed by the gas that is to be detected. The light received by the light-receiving element 12 in the present embodiment is infrared light, but the light is not limited to infrared light. The light-receiving element 12 converts received light to an electrical signal and outputs the converted electrical signal. The electrical signal is output to the IC 13, for example. The IC 13 that receives the electrical signal computes a concentration of the gas that is to be detected based on the transmittance of light, for example.

The light guide 15 is a member that guides light emitted from the light-emission surface of the light-emitting element 11 to the light-receiving element 12 that has the light-irradiation surface. The light guide 15 is an optical system of the gas sensor 1. The light guide 15 includes an optical member and constitutes a light path from the light-emitting element 11 to the light-receiving element 12. The optical member may be a mirror, a lens, or the like, for example. In the present embodiment, the light guide 15 is adhered to the substrate at an adhesion surface 17 of the front surface 30a of the substrate and forms a space into which a gas is introduced. Light emitted from the light-emitting element 11 is caused to pass through the gas in the space and be received by the light-receiving element 12 through the light guide 15. In a situation in which the gas that is to be detected is included in the gas in the space, light of a particular wavelength is absorbed in accordance with the concentration, thereby enabling measurement of the concentration of the gas that is to be detected through detection of the amount of absorption.

The optical filter 16 is a member having a wavelength selection function. The optical filter 16 may be a bandpass filter that transmits light in an absorption wavelength band of the gas that is to be detected. The optical filter 16 is provided at an emission surface of the light-emitting element 11 in the present embodiment, but is not limited thereto. For example, the optical filter 16 may be provided at a light-receiving surface (irradiation surface) of the light-receiving element 12.

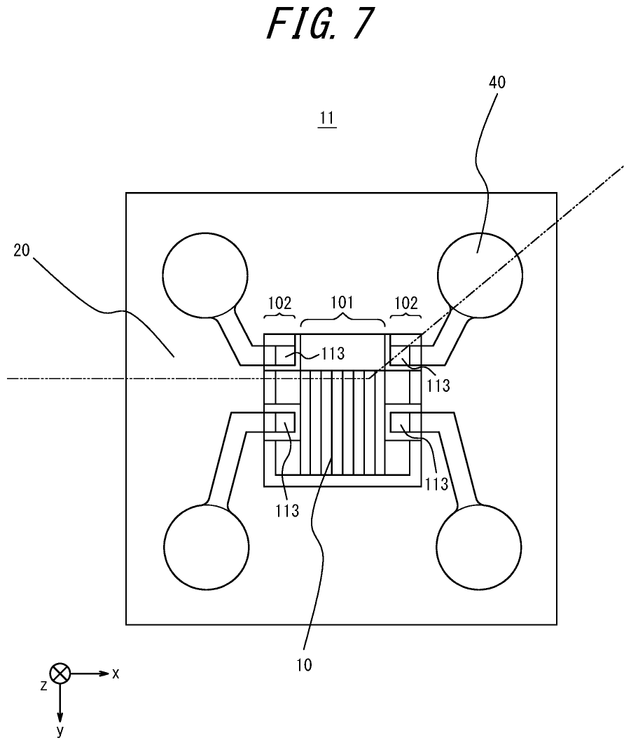

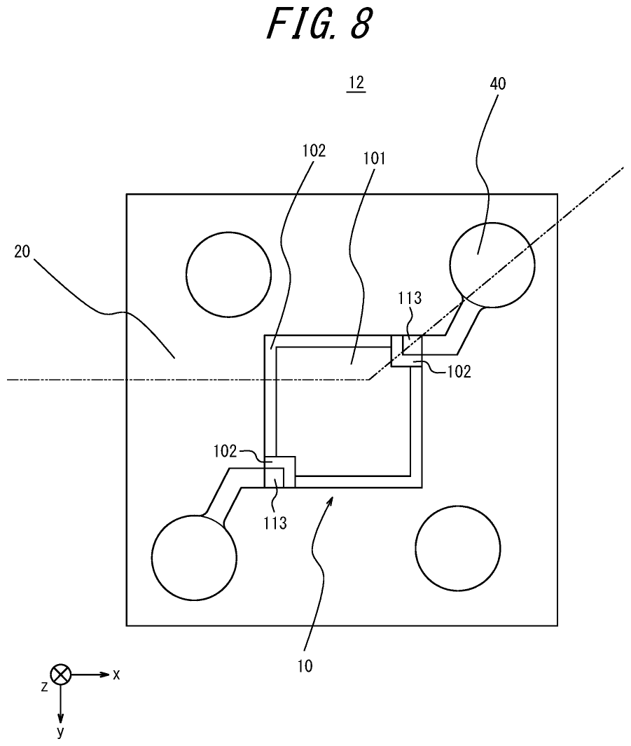

FIG. 5 is a cross-sectional view illustrating a partially enlarged cross-section including a photoelectric conversion element of the gas sensor 1 illustrated in FIG. 1. The photoelectric conversion element is the light-emitting element 11 or the light-receiving element 12. Terms for the photoelectric conversion element may be used when describing structures that are common to both the light-emitting element 11 and the light-receiving element 12. The enlarged cross-section illustrated in FIG. 5 is a cross-section at an imaginary line that cuts across the external connection terminal 40 in the light-emitting element 11 or the light-receiving element 12, as illustrated in FIG. 7 or FIG. 8.

As illustrated in FIG. 5, an electrode 113 is provided at a surface at an opposite side to a light emission/irradiation surface 10a of a semiconductor element member 10 included in the photoelectric conversion element. An electrode formation surface 10b, which is the surface of the semiconductor element member 10 where the electrode 113 is formed, is in contact with the redistribution layer 30. The semiconductor element member 10 is electrically connected to the redistribution layer 30 via the electrode 113.

The semiconductor substrate 111 is an element substrate on which it is possible to form a semiconductor layer 112 having a PN junction or PIN junction photodiode structure. No specific limitations are placed on the semiconductor substrate 111 so long as it displays light transmittance of infrared light or the like. The semiconductor substrate 111 may include a material that contains a semiconductor or may be electrically insulating. The semiconductor substrate 111 may, for example, be formed of silicon (Si), gallium arsenide (GaAs), sapphire, indium phosphide (InP), or the like. In a case in which the semiconductor layer 112 is formed of a material containing a narrow gap semiconductor material including In, Sb, As, Al, or the like (for example, InSb), it is preferable to use a GaAs substrate as the semiconductor substrate 111 from the perspective of forming the semiconductor layer 112 to have few lattice defects. In this case, the semiconductor substrate 111 displays high transmittance of light and enables high-quality crystalline growth thereon. In addition, irregularities may be formed or an antireflection film of TiO₂ or the like may be formed at the surface on the light emission/irradiation surface 10a side of the semiconductor substrate 111. This makes it possible to improve light extraction.

The semiconductor layer 112 may, for example, have a PIN junction photodiode structure that includes a first conductivity type semiconductor layer, an active layer, and a second conductivity type semiconductor layer. The semiconductor layer 112 is not limited to a particular structure so long as it has a PIN junction or PN junction photodiode structure or LED structure. A commonly known substance having sensitivity to light of a particular wavelength such as infrared light can be adopted in the semiconductor layer 112. For example, InSb can be adopted. The electrode 113 is formed on the semiconductor layer 112.

A seal 20 that is formed of a resin material covers a side surface of the semiconductor element member 10 in a manner such that the light emission/irradiation surface 10a of the semiconductor element member 10 is exposed. In addition, the electrode formation surface 10b of the semiconductor element member 10 is exposed to the redistribution layer 30. In other words, in the gas sensor 1 according to the present embodiment, the semiconductor element member 10 is sealed by the seal 20 with the exception of the light emission/irradiation surface 10a and the electrode formation surface 10b thereof. The portion including the semiconductor element member 10 and the seal 20 is also referred to as a semiconductor module 21. No specific limitations are placed on the surface covered by the seal 20 so long as the seal 20 is formed in a manner such that light (infrared light and the like) can be emitted from or irradiate the semiconductor layer 112 via the semiconductor substrate 111. For example, the seal 20 may cover a portion of the electrode formation surface 10b of the semiconductor element member 10 or may not cover a portion of the side surface of the semiconductor element member 10. An upper surface of a portion of the seal 20 that covers the side surface of the semiconductor element member 10 may be thinner than the light emission/irradiation surface 10a or may be flush with the light emission/irradiation surface 10a.

From the perspective of mass producibility, mechanical strength, and stress on the semiconductor element member 10, it is preferable that a resin material having a similar linear expansion coefficient to the redistribution layer 30 is used as the seal 20. For example, the seal 20 may be formed of a resin material such as epoxy resin.

Besides a resin material such as epoxy resin, the material forming the seal 20 may contain a filler, impurities that are unavoidably mixed in, and so forth. Silica, alumina, or the like, for example, may suitably be used as the filler.

The redistribution layer 30 is formed at the electrode formation surface 10b side of the semiconductor element member 10 and the seal 20. The redistribution layer 30 includes an insulating layer 31 configured to include a first insulating layer 311 and a second insulating layer 312 with a redistribution wire 32 provided therebetween, the redistribution wire 32 electrically connected to the electrode 113 of the semiconductor element member 10, and a pad 33 for connection of the external connection terminal 40. In the present embodiment, the redistribution wire 32 is connected to the electrode 113, and the redistribution wire 32 is connected to the external connection terminal 40. The insulating layer 31 is provided on one surface of the semiconductor module 21 and covers at least the redistribution wire 32 of the electrode 113 and of the external connection terminal 40.

The first insulating layer 311 is formed at the electrode formation surface 10b side of the semiconductor element member 10 and the seal 20. The first insulating layer 311 is formed of a material having little warping, excellent cohesion with the redistribution wire 32, and high heat resistance. Specifically, the first insulating layer 311 is formed of a resin material such as polyimide. The first insulating layer 311 has an opening that penetrates through the first insulating layer 311 at a position of the electrode 113 of the semiconductor element member 10. The redistribution wire 32 can be electrically connected to the electrode 113 via the opening.

The redistribution wire 32 is provided between the first insulating layer 311 and the second insulating layer 312. The redistribution wire 32 covers a front surface of the electrode 113 that is exposed from the opening in the first insulating layer 311. The redistribution wire 32 extends along a front surface of the first insulating layer 311 from the side wall of the opening to the pad 33.

The redistribution wire 32 may be configured to include a conductor layer formed above a foundation layer formed by electroless plating or sputtering, for example. The foundation layer also fulfills a role of improving adhesiveness between the first insulating layer and the conductor layer. The foundation layer may be formed of copper (Cu), for example. The conductor layer is formed by electrolytic plating, for example. The conductor layer is formed of copper (Cu), for example.

The second insulating layer 312 is formed at the front surface of the first insulating layer 311. The second insulating layer 312 is formed of a resin material such as polyimide, for example, in the same manner as the first insulating layer 311. The second insulating layer 312 has an opening that penetrates through the second insulating layer 312 in a region that does not overlap with the opening in the first insulating layer 311 in plan view. The pad 33 can be electrically connected to the redistribution wire 32 via the opening. The first insulating layer 311 may be formed of the same material as the second insulating layer 312. In this case, the insulating layer 31 at the height from the semiconductor module 21 to the surface of the redistribution wire 32 on the semiconductor module 21 side becomes the first insulating layer 311, and the portion of the insulating layer 31 from the surface of the redistribution wire 32 on the semiconductor module 21 side to the opposite side from the semiconductor module 21 becomes the second insulating layer 312.

The pad 33 is provided in order to connect the external connection terminal 40 to the redistribution wire 32. The pad 33 is formed of a laminate film of a Ni layer and a Au layer, for example. The pad 33 covers the front surface of the redistribution wire 32 that is exposed from the opening in the second insulating layer 312.

The external connection terminal 40 is in contact with the pad 33 and is electrically connected to the redistribution wire 32 that is exposed from the opening in the second insulating layer 312. In the present embodiment, a plurality of external connection terminals 40 is provided and forms a land grid array (LGA). However, no limitations are placed on the shape and the like of the external connection terminal 40. The external connection terminal 40 may be a solder ball, for example. A plurality of external connection terminals 40 may form a ball grid array (BGA), for example.

The gas sensor 1 includes the light-emitting element 11 and the light-receiving element 12 and detects a detection target gas contained in a gas, based on the received light amount of light that is emitted from the light-emitting element 11, passes through the gas, and is detected by the light-receiving element 12. The light-emitting element 11 and the light-receiving element 12 each have the configuration of the aforementioned semiconductor element member 10. In the light-emitting element 11, the light emission/irradiation surface 10a of the semiconductor element member 10 emits light. In the light-receiving element 12, the light emission/irradiation surface 10a of the semiconductor element member 10 is irradiated by light. In a situation in which the gas sensor 1 is mounted on a product substrate to be used as a component of a product such as a measurement instrument, for example, the plurality of external connection terminals 40 is soldered by reflow at a specific position on the product substrate.

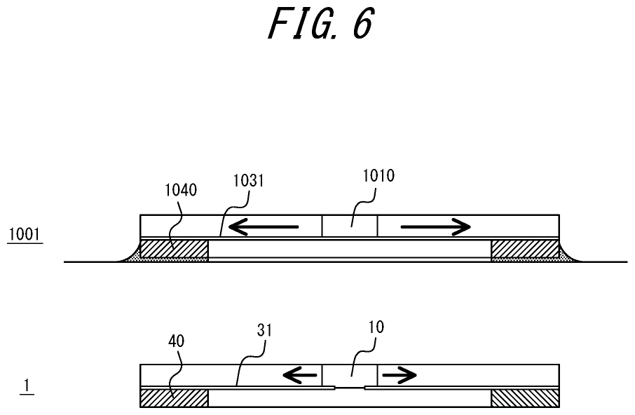

Conventionally, there have been instances in which force acts on a substrate of an optical device under the influence of thermal expansion caused by reflow during mounting of the optical device or contraction caused by subsequent cooling, thereby resulting in deformation of an optical element and characteristic variation of the optical device. For example, as illustrated in the upper diagram in FIG. 6, in the case of a small gas sensor 1001 having a conventional structure in which external connection terminals 1040 are an LGA, the LGA package contracts when the temperature falls after reflow due to the LGA package having a larger linear expansion coefficient than the product substrate. This results in stress pulling toward the external connection terminals 1040 that are connected to the product substrate. Since the insulating layer 1031, which is connected to both external connection terminals 1040, covers the semiconductor element member 1010 of the photoelectric conversion element, the stress is applied to the semiconductor element member 1010 through the insulating layer 1031. This may lead to the region of the semiconductor element member 1010 related to light emission and reception being deformed by being pulled toward the plurality of external connection terminals 1040, resulting in characteristic variation of the gas sensor 1.

In the gas sensor 1 according to the present embodiment, the insulating layer 31 is formed in the semiconductor element member 10 of the photoelectric conversion element so as not to cover at least a portion of the semiconductor layer 112, or so as to cover at least a portion of the semiconductor layer 112 thinly as compared to the thickness of the insulating layer 31 that covers the redistribution wire 32. For example, as illustrated in FIG. 6, the insulating layer 31 is separated so as not to cover the region of the semiconductor layer 112 related to light emission and reception. The stress that pulls the semiconductor element member 10 toward the external connection terminal 40 is thereby reduced, and deformation of the semiconductor substrate 111 is suppressed, enabling suppression of the occurrence of characteristic variation in the gas sensor 1.

Some examples of the formation of the insulating layer 31 are described below. FIG. 7 is a plan view of a case in which the photoelectric conversion element is the light-emitting element 11. As illustrated in FIG. 7, the semiconductor layer 112 of the light-emitting element 11 can be divided into a connection region 102 in which the electrode 113 can be disposed and a central region 101 excluding the connection region 102. The central region 101 is the region of the semiconductor layer 112 related to receiving and emitting light. In particular, if the central region 101 is pulled in different directions and deforms, characteristic variation will occur in the gas sensor 1. Therefore, characteristic variation in the gas sensor 1 can be suppressed by weakening the stress applied to the central region 101, preventing stress from being applied to the central region 101, or ensuring that the stress applied to the central region 101 is mainly in one direction. FIG. 8 is a plan view of a case in which the photoelectric conversion element is the light-receiving element 12. As illustrated in FIG. 8, the semiconductor layer 112 can be divided into a connection region 102 and a central region 101 in the light-receiving element 12 as well.

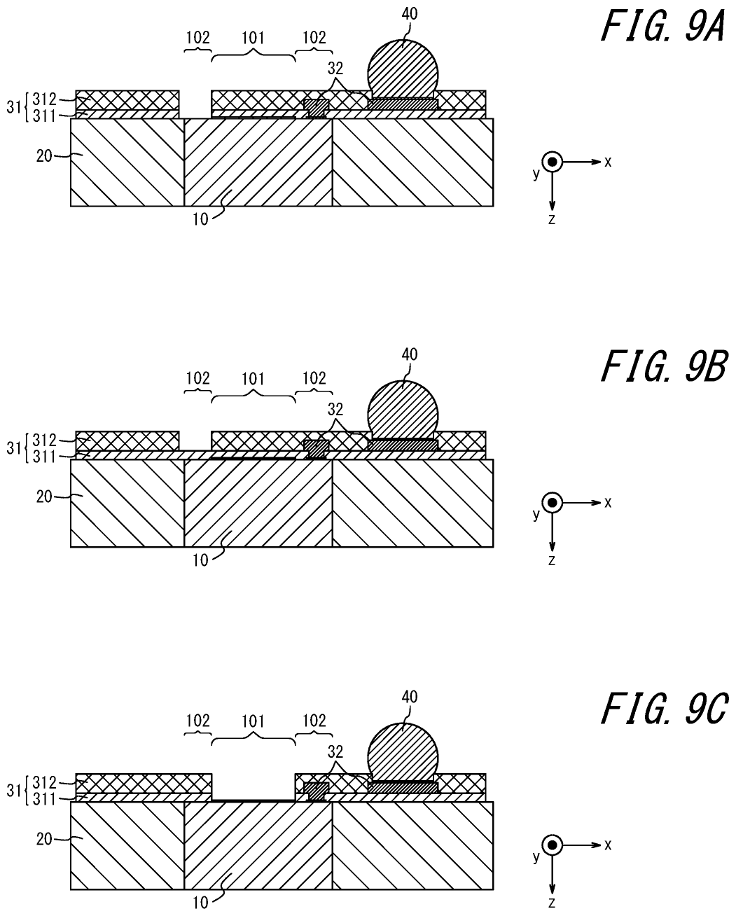

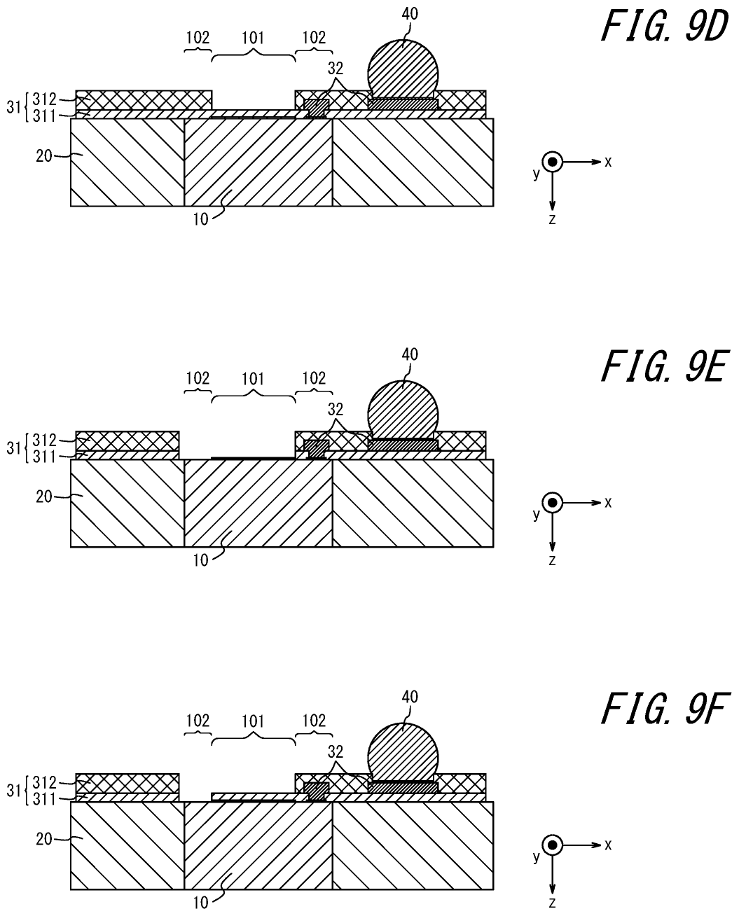

FIGS. 9A to 9F are cross-sectional views illustrating an example configuration of the insulating layer 31 of the photoelectric conversion element (i.e. the light-emitting element 11 or the light-receiving element 12). The cross-sections of the photoelectric conversion elements in FIGS. 9A to 9F are cross-sections at a virtual line crossing the external connection terminal 40 as illustrated in FIG. 7 or FIG. 8.

As illustrated in FIG. 9A, the insulating layer 31 may be formed so as not to cover a portion of the connection region 102. The insulating layer 31 can be separated so that the stress on the central region 101 is primarily in one direction. In the example in FIG. 9A, stress in the positive direction of the x-axis is applied to the central region 101, but by the insulating layer 31 being separated, not much stress is applied in the negative direction of the x-axis. The deformation of the semiconductor substrate 111 is therefore suppressed, and the occurrence of characteristic variation in the gas sensor 1 can be suppressed. Furthermore, in the semiconductor element member 10 of the photoelectric conversion element, the portion not covered by the insulating layer 31 is in contact with a gas (air). The reflectance is thereby larger than in the case of contact with the insulating layer 31. As a result, light heading in the negative direction of the z-axis is reflected in the portion in contact with the gas and returns to the light emission/irradiation surface 10a or the semiconductor layer 112, thereby improving the light emission efficiency of the light-emitting element 11 or the light reception sensitivity of the light-receiving element 12.

As illustrated in FIG. 9B, the insulating layer 31 may be formed so as to cover a portion of the connection region 102 thinly as compared to the thickness of the insulating layer 31 that covers the redistribution wire 32. Even if the insulating layer 31 is not completely separated, the stress on the central region 101 can be reduced by a portion of the insulating layer 31 being thin. The thickness of the insulating layer 31 covering the redistribution wire 32 is indicated by “T” in FIG. 5 and is the combined thickness of the first insulating layer 311 and the second insulating layer 312. In a case in which the insulating layer 31 is formed so as to cover at least a portion of the semiconductor layer 112 thinly, the thinly covering portion of the insulating layer 31 preferably has a thickness that is equal to or less than ½ of the combined thickness of the first insulating layer 311 and the second insulating layer 312 (equal to or less than T/2). In the example in FIG. 9B, the thickness of the first insulating layer 311 is equal to or less than the thickness of the second insulating layer 312. At the portion of the insulating layer 31 that thinly covers a portion of the connection region 102, coverage is provided only by the first insulating layer 311, which is equal to or less than T/2.

As illustrated in FIG. 9C, the insulating layer 31 may be formed so as not to cover the central region 101. Such separation of the insulating layer 31 can prevent stress from being applied to the central region 101. Therefore, the deformation of the semiconductor substrate 111 is suppressed, and the occurrence of characteristic variation in the gas sensor 1 can be suppressed. In addition, as in the case of FIG. 9A, the light emission efficiency of the light-emitting element 11 or the light reception sensitivity of the light-receiving element 12 can be improved.

As illustrated in FIG. 9D, the insulating layer 31 may be formed so as to cover the central region 101 thinly as compared to the thickness of the insulating layer 31 that covers the redistribution wire 32. Even if the insulating layer 31 is not completely separated, the stress on the central region 101 can be reduced by a portion of the insulating layer 31 being thin. Here, as in FIG. 9B, the thinly covering portion of the insulating layer 31 preferably has a thickness that is equal to or less than ½ of the combined thickness of the first insulating layer 311 and the second insulating layer 312 (equal to or less than T/2). In the example in FIG. 9D, at the portion of the insulating layer 31 that thinly covers the central region 101, the second insulating layer 312 is not provided, and coverage is provided only by the first insulating layer 311. The thickness of the portion of the insulating layer 31 that thinly covers the central region 101 is therefore equal to or less than T/2.

As illustrated in FIG. 9E, the insulating layer 31 may be formed so as not to cover the central region 101 and a portion of the connection region 102. Such separation of the insulating layer 31 can prevent stress from being applied to the central region 101. Therefore, the deformation of the semiconductor substrate 111 is suppressed, and the occurrence of characteristic variation in the gas sensor 1 can be suppressed. In addition, as in the case of FIG. 9A, the light emission efficiency of the light-emitting element 11 or the light reception sensitivity of the light-receiving element 12 can be improved.

As illustrated in FIG. 9F, the insulating layer 31 may be formed so as to cover the central region 101 and a portion of the connection region 102 thinly as compared to the thickness of the insulating layer 31 that covers the redistribution wire 32. Even if the insulating layer 31 is not completely separated, the stress on the central region 101 can be reduced by a portion of the insulating layer 31 being thin. Here, as in FIG. 9B, the thinly covering portion of the insulating layer 31 preferably has a thickness that is equal to or less than ½ of the combined thickness of the first insulating layer 311 and the second insulating layer 312 (equal to or less than T/2). In the example in FIG. 9F, at the portion of the insulating layer 31 that thinly covers the central region 101 and a portion of the connection region 102, coverage is provided only by the first insulating layer 311, which is equal to or less than T/2.

In this manner, the photoelectric conversion element and the gas sensor 1 according to the present embodiment can suppress characteristic variation caused by deformation of a semiconductor substrate 111 as compared to a conventional structure through the configuration set forth above.

Although an embodiment of the present disclosure has been described based on the various drawings and examples, it should be noted that a person of ordinary skill in the art could easily make various modifications and revisions based on the present disclosure. Accordingly, such modifications and revisions should also be considered to be included within the scope of the present disclosure. For example, functions and the like included in various constituent parts, etc., may be rearranged so long as they are logically consistent. Moreover, a plurality of constituent parts, etc., may be combined as a single part or may be split up.

1. A photoelectric conversion element comprising:
a semiconductor module comprising a semiconductor element member and a seal covering a side of the semiconductor element member, the semiconductor element member including a light emission/irradiation surface configured to emit light or to be irradiated by light, a semiconductor substrate, a semiconductor layer, and an electrode; and
an insulating layer provided on one surface of the semiconductor module and covering a redistribution wire of the electrode and of at least one external connection terminal,
wherein the insulating layer is configured to include a first insulating layer and a second insulating layer, the redistribution wire being provided between the first insulating layer and the second insulating layer, and is formed so as not to cover at least a portion of the semiconductor layer, or so as to cover at least a portion of the semiconductor layer thinly as compared to a thickness of the insulating layer that covers the redistribution wire.

2. The photoelectric conversion element according to claim 1, wherein in a case in which the insulating layer is formed to cover at least a portion of the semiconductor layer thinly, the second insulating layer is not provided at a thinly covering portion of the insulating layer.

3. The photoelectric conversion element according to claim 1, wherein the photoelectric conversion element has a fan out wafer level package structure.

4. The photoelectric conversion element according to claim 1, wherein in a case in which the semiconductor layer is divided into a connection region in which the electrode can be disposed and a central region excluding the connection region, the insulating layer is formed so as not to cover a portion of the connection region or so as to cover a portion of the connection region thinly as compared to the thickness of the insulating layer that covers the redistribution wire.

5. The photoelectric conversion element according to claim 1, wherein in a case in which the semiconductor layer is divided into a connection region in which the electrode can be disposed and a central region excluding the connection region, the insulating layer is formed so as not to cover the central region or so as to cover the central region thinly as compared to the thickness of the insulating layer that covers the redistribution wire.

6. The photoelectric conversion element according to claim 1, wherein in a case in which the semiconductor layer is divided into a connection region in which the electrode can be disposed and a central region excluding the connection region, the insulating layer is formed so as not to cover the central region and a portion of the connection region or so as to cover the central region and a portion of the connection region thinly as compared to the thickness of the insulating layer that covers the redistribution wire.

7. The photoelectric conversion element according to claim 1, wherein the at least one external connection terminal comprises a plurality of external connection terminals and forms a land grid array or a ball grid array.

8. A gas sensor comprising:
a light-emitting element that is the photoelectric conversion element according to claim 1, the light emission/irradiation surface of the light-emitting element being configured to emit light; and
a light-receiving element that is the photoelectric conversion element according to claim 1, the light emission/irradiation surface of the light-receiving element being configured to be irradiated by light,
wherein the gas sensor is configured to detect a detection target gas contained in a gas, based on a received light amount of the light that is emitted from the light-emitting element, passes through the gas, and is detected by the light-receiving element.

9. The photoelectric conversion element according to claim 1, wherein in a case in which the insulating layer is formed to include a thinly covering portion that covers at least a portion of the semiconductor layer thinly, the thinly covering portion has a thickness that is equal to or less than ½ of a combined thickness of the first insulating layer and the second insulating layer.
